(19) United States
(12) Patent Application Publication
(10) Pub. No.: US 2006/0132214 A1
(43) Pub. Date: Jun. 22, 2006

(54) LEVEL SHIFTER

(76) Inventor: Chuen-Shiu Chen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,241

(22) Filed: Mar. 25, 2005

(30) Foreign Application Priority Data
Dec. 16, 2004 (TW) 93139101

(51) Int. Cl. H03L 5/00

(52) U.S. Cl. 327/333

(57) ABSTRACT

A level shifter comprises first/second/third/fourth transistors and an inverter. The first nodes of the first transistor and the third transistor couple to a first voltage. The first node of the second transistor couples to the third node of the first transistor. The second node of the second transistor receives input signal. The third node of the second transistor couples to ground. The inverter receives the input signal and outputs an inverse signal. The second node of the third transistor couples to the third node of the first transistor. The first node of the fourth transistor couples to the second node of the first transistor and the third node of the third transistor. In addition, the first node of the fourth transistor transmits the output signal. The second node of the fourth transistor receives the inverse signal. The third node of the fourth transistor couples to ground.

### CROSS-REFERENCE TO RELATED APPLICATION

This application claims the priority benefit of Taiwan application serial no. 931391 01, filed on Dec. 16, 2004.

### BACKGROUND OF THE INVENTION

1. Field of the Invention

This invention generally relates to a level shifter, and particularly to a level shifter which can reduce current leakage occurred in a circuit.

2. Description of Related Art

In recent years, an increasing number of microcomputers are designed to have a large number of devices such as an ASIC, a microprocessor, a memory, and a peripheral circuit mounted on a mother board of a computer to satisfy a desirable function. In particular, the ASIC and the microcomputer are designed such that an amplitude of a power source voltage used in the inside becomes smaller, because a reduction in consumption power and operation at a high frequency are required. For example, an internal power source voltage is 2.5V. This voltage is expected to decrease to 1.8 V, 1.5 V, and 1.2 V in the future. In contrast to this, in many cases, in accordance with a JEDEC system interface standard or the like, data input and output operation between respective devices is conducted at 3.3V and a device such as the peripheral circuit is operated at 3.3 V. Therefore, occurrence of a situation in which the peripheral circuit is operated at a voltage different from operating voltages of the ASIC and the microcomputer is becoming more frequent. Thus, the ASIC and the microcomputer are provided with input and output buffers in order to adjust a voltage difference between the inside and the outside by level shifting.

FIG. 1 is a drawing schematically shows a view of a conventional circuit level shifter. As shown in the figure, the level shifter comprises 6 transistors 101˜111. Wherein, the gates of the transistor 109 and the transistor 111 receive an input signal. With the input signal the output node of the level shifter can be controlled as whether or not an output voltage should be exported for the use of the next serially connected circuit.

In the conventional level shifter, the voltage VCC3I, which is coupled to the transistor 101 and the transistor 105, is controlled by the voltage VCCK which is coupled to the transistor 109. The voltage VCCK connected earlier than the voltage VCC3I is usually recommended.

In accordance with the above mentioned situation, at the moment that the level shifter is conducted, the input signal is in a state of low potential level. Since the voltage VCCK has been connected but the voltage VCC3I has not been connected yet, the transistor 111 is still in the OFF state. Thus, a current leakage I flows from the voltage VCCK to the voltage VCC3I through the transistor 109, the transistor 103 and the transistor 101. Consequently, the level shifter unnecessarily generates an erroneous action and increases power wastage in the circuit.

### SUMMARY OF THE INVENTION

An object of the present invention is to provide a level shifter. The present invention provides a modification of conventional coupling manner of the transistors in a level shifter to solve current leakage problem in a circuit.

The present invention provides a level shifter for receiving an input signal. The level shifter includes a first transistor, a second transistor, an inverter, a third transistor and a fourth transistor. Wherein, a first source/drain of the first transistor is coupled to a first voltage. A first source/drain of the second transistor is coupled to a second source/drain of the first transistor, a gate of the second transistor receives the input signal, and a second source/drain of the second transistor is coupled to the ground.

The inverter receives the input signal and outputs an inverse signal. A first source/drain of the third transistor is coupled to the first voltage, and a gate of the third transistor is coupled to the second source/drain of the first transistor. A first source/drain of the fourth transistor coupled to a gate of the first transistor and a second source/drain of the third transistor outputs an output signal. A second gate of the fourth transistor receives the inverse signal, and a second source/drain of the fourth transistor is coupled to the ground.

Wherein, the first transistor and the third transistor are first-type MOSFETs, and the second transistor and the fourth transistor are second-type MOSFETs.

In accordance with the level shifter of a preferred embodiment of the present invention, the first and the third transistors are P-type MOSFETs, and the second and the fourth transistors are N-type MOSFETs.

In accordance with the level shifter of the preferred embodiment of the present invention, the inverter includes a fifth transistor and a sixth transistor. Wherein, a first source/drain of the fifth transistor is coupled to a second voltage, and a gate of the fifth transistor receives the input signal. A first source/drain of the sixth transistor is coupled to a second source/drain of the fifth transistor and outputs an inverse signal. A gate of the sixth transistor receives the input signal, and a second source/drain of the sixth transistor is coupled to the ground.

In accordance with the level shifter of the preferred embodiment of the present invention, the second voltage controls the output of the first voltage.

In accordance with the level shifter of the preferred embodiment of the present invention, the fifth transistor is a P-type MOSFET, and the sixth transistor is an N-type MOSFET.

In summary of the above mentioned, the level shifter of the present invention, owing to amending a coupling manner of a transistor in a conventional level shifter, can solve the defect of the current leakage in the circuit and decrease the unnecessary power wastage in the circuit.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

FIG. 1 is a drawing schematically showing a circuit diagram of a conventional level shifter.

FIG. 2 is a drawing schematically showing a circuit diagram of a level shifter of the present invention.

FIG. 3 is a table schematically showing a comparison of current between a conventional level shifter and a level shifter of the present invention under various situations.

FIG. 4, FIG. 5 and FIG. 6 are drawings schematically showing waveforms of input signal and output signal between a conventional level shifter and a level shifter of the present invention under different voltage supply situations.

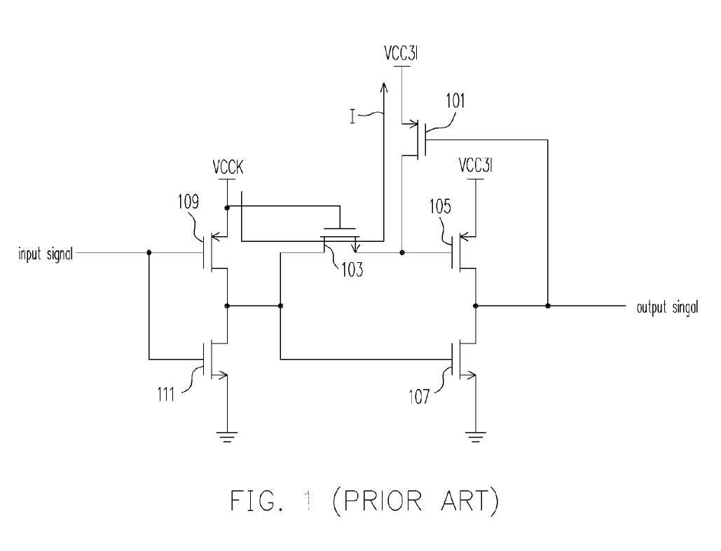

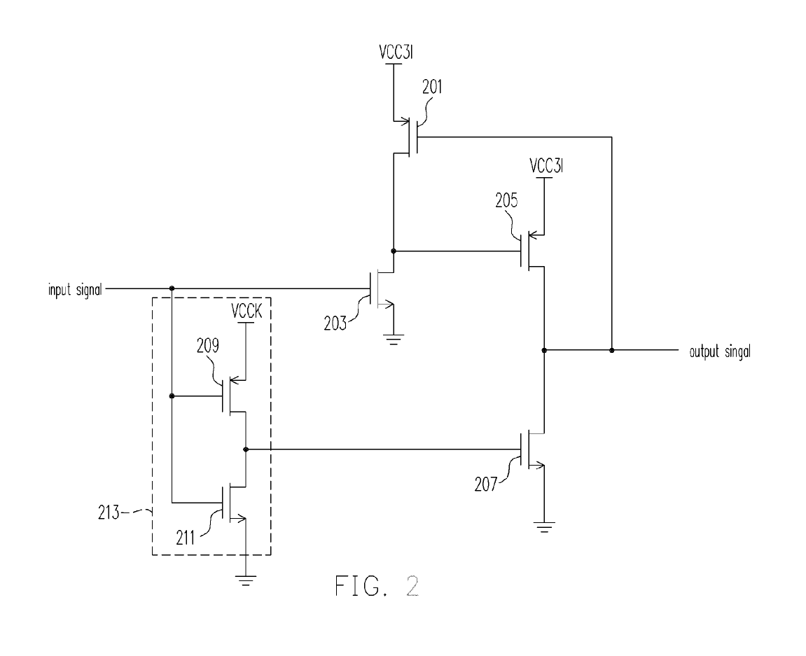

### DESCRIPTION OF THE PREFERRED EMBODIMENTS

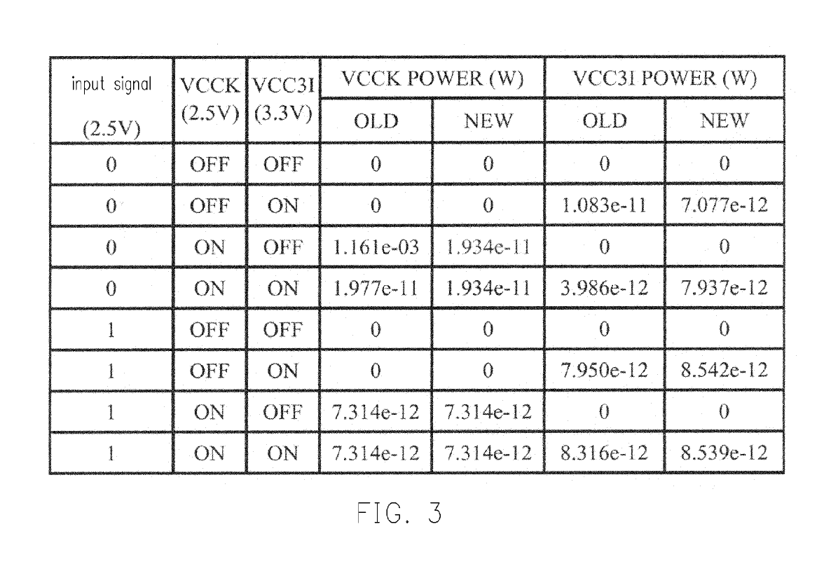

FIG. 2 is a drawing schematically showing a circuit diagram of a level shifter of the present invention. As shown in the figure, the level shifter comprises a first transistor 201, a second transistor 203, a third transistor 205, a fourth transistor 207 and an inverter 21 3. The first transistor 201 and the third transistor 205 are P-type MOSFETs, and the second transistor 203 and the fourth transistor 207 are N-type MOSFETs.

Moreover, the inverter 213 comprises a fifth transistor 209 and a sixth transistor 211. Wherein, the fifth transistor 209 is a P-type MOSFET, and the sixth transistor 211 is an N-type MOSFET. Of course, inverters with other models can be used in the circuit of the present invention.

In the embodiment of the present invention, gates of the fifth transistor 209, the sixth transistor 211 and of the second transistor 203 together receive an input signal. The second transistor 203 is at OFF state when the input signal is a low potential level voltage signal. The inverter 213 which comprises the fifth transistor 209 and the sixth transistor 211, due to the low potential level voltage signal of the received input signal, outputs a high potential level inverse voltage signal to a gate of the fourth transistor 207. Hence, the fourth transistor 207 will be at ON state, and the output voltage of the level shifter is therefore a low potential level voltage signal.

Because that the gate of the first transistor 201 is coupled to the output node of the level shifter, therefore, when the output voltage of the level shifter is a low potential level voltage signal, the first transistor 201 can be at ON state, and the gate of the third transistor 205 can be at a high potential level voltage signal state so that the third transistor 205 will be at OFF state.

On the contrary, when the input signal is a high potential level voltage signal, the second transistor 203 will be at ON state, and the signal at the gate of the third transistor 205 is transformed to a low potential voltage signal so that the third transistor 205 is also at ON state. Accordingly, the first voltage VCC3I is connected.

Since the input signal received by the inverter 213 is a high potential level voltage signal, the inverter 213 outputs a low potential level inverse voltage signal to the gate of the fourth transistor 207. The fourth transistor 207 will be at OFF state and the output voltage of the level shifter can therefore be a high potential level voltage signal such as the first voltage VCC3I.

In the embodiment of the present invention, the first voltage VCC3I, which is coupled to the first transistor 201 and the third transistor 205, is controlled by the second voltage VCCK which is coupled to the inverter 213. Similarly with the conventional technology, in the connecting sequence of the voltages of the level shifter, the second voltage VCCK is usually connected earlier than the first voltage VCC3I.

However, in the embodiment of the present invention, the coupling manner of the second transistor 203 is different with the conventional coupling manner of the transistor 103. One node of the second transistor 203 is coupled to the ground directly in the embodiment. Therefore, at the moment that the level shifter is connected, the input signal is still at a state of low potential level of voltage signal. The second voltage VCCK has been connected already, but the first voltage VCC3I has not been connected yet that the path which formerly caused a current leakage does not exist any longer. As a result, the problem of current leakage will not occur.

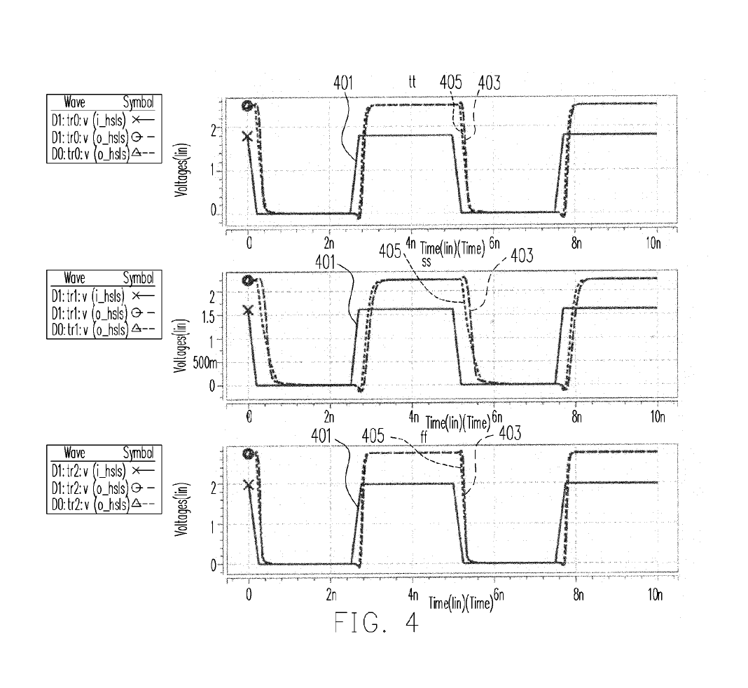

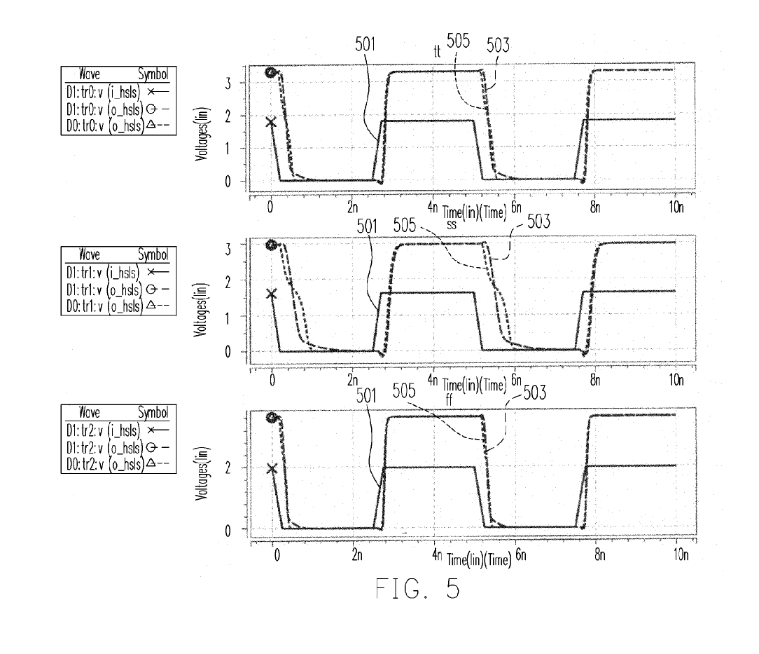

FIG. 3 is a table schematically showing a comparison of power consumption between a conventional level shifter and a voltage shifter of the present invention under several situations. OLD indicated in the table of FIG. 3 represents the power consumption of the conventional level shifter, and NEW in the table of FIG. 3 is the power consumption of the voltage shifter of the present invention.

As the above mentioned, as shown on the fourth row of FIG. 3, when the input signal is at a state of low potential level voltage signal, the second voltage VCCK has been connected. While the first voltage VCC3I has not been connected yet, the power consumption of the voltage VCCK of the conventional level shifter is 1.161e-03 (W). Under the same situation, in the level shifter of the embodiment of the present invention, the path which formerly caused a current leakage does not exist any longer so that the power consumption of the voltage VCCK is 1.934e-11 (W). Compared with the convention circuit, the current value generated has been greatly improved.

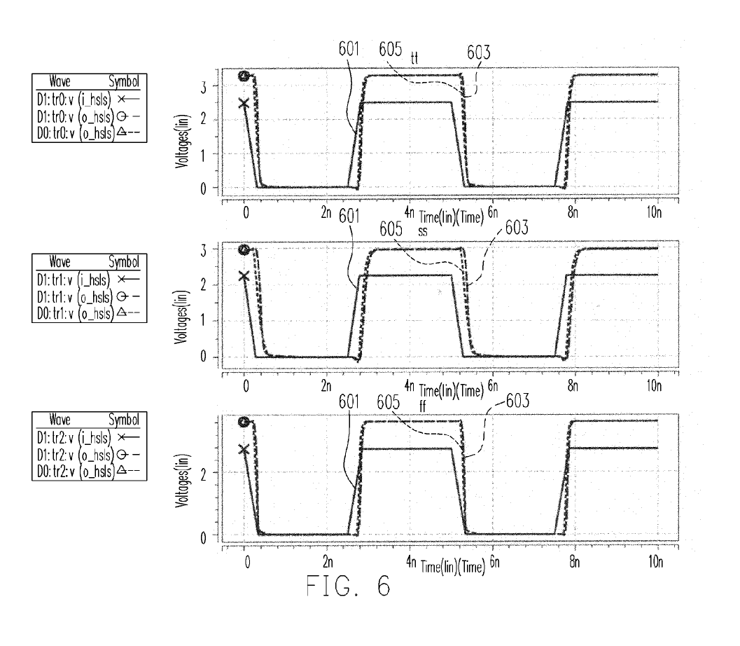

FIG. 4, FIG. 5 and FIG. 6 are drawings schematically showing waveforms of input signal and output signal between a conventional level shifter and a level shifter of the present invention under different voltage supply situations. First, FIG. 4 schematically shows the output waveforms of the conventional level shifter and the level shifter in the embodiment of the present invention. This figure illustrates a comparison of the waveforms when the second voltage VCCK is 1.8V and the first voltage VCC3I is 2.5V under a same input signal condition.

Furthermore, the waveform diagrams as shown in FIG. 4 compare separately the changes of the waveforms of different three model transistors. From top to bottom, the three transistors are tt(typical NMOS, typical PMOS, 25° C.), ss(slow NMOS, slow PMOS, 125° C.)and ff(fast NMOS, fast PMOS, −40° C.).

Wherein, waveform 401 is the input signal in the circuit, waveform 403 is the output waveform of the conventional level shifter, waveform 405 is the output waveform of the level shifter in the embodiment of the present invention. This figure illustrates a comparison of the waveforms when the second voltage VCCK is 1.8V and the first voltage VCC3I is 2.5V under the same input signal condition. After comparing the waveforms in the drawing, it can be understood that the waveforms of the conventional level shifter and that in the embodiment of the present invention are almost the same and overlapped.

FIG. 5 schematically shows the output waveforms of the conventional level shifter and the level shifter in the embodiment of the present invention This figure illustrates a comparison of the waveforms when the second voltage VCCK is 1.8V and the first voltage VCC3I is 3.3V under the same input signal condition. Similarly, the waveform diagrams as shown in this figure compare separately the changes of the waveforms of different three model transistors. From top to bottom, the three transistors are tt, ss and ff.

Wherein, waveform 501 is the input signal, waveform 503 is the output waveform of the conventional level shifter, waveform 505 is the output waveform of the level shifter in the embodiment of the present invention. After comparing the waveforms in the drawing, it can be understood that, except a minor drift on the descending margins of the ss type transistor, the waveforms of the conventional level shifter and that of the embodiment of the present invention are almost the same and overlapped.

Finally, FIG. 6 schematically shows the output waveforms of the conventional level shifter and the level shifter in the embodiment of the present invention. This figure illustrates a comparison of the waveforms when the second voltage VCCK is 2.5V and the first voltage VCC3I is 3.3V under the same input signal condition. Similarly, the waveform diagrams as shown in this figure compare separately the changes of the waveforms of different three model transistors. From top to bottom, the three transistors are tt, ss and ff.

Wherein, waveform 601 is the input signal, waveform 603 is the output waveform of the conventional level shifter, waveform 605 is the output waveform of the level shifter in the embodiment of the present invention. After comparing the waveforms in the drawing, it can be understood that the waveforms of the conventional level shifter and that in the embodiment of the present invention are almost the same and overlapped.

In summary of the above mentioned, the level shifter of the present invention is a modification of the conventional coupling manner of a transistor in a level shifter. The level shifter does not only maintain the previously existing function in the circuit, but, more importantly, also solve the current leakage problem in a circuit. Thus, power wastage in the circuit is decreased.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A level shifter, suitable for receiving an input signal, comprising:
a first transistor, wherein a first source/drain of the first transistor is coupled to a first voltage;
a second transistor, wherein a first source/drain of the second transistor is coupled to a second source/drain of the first transistor, a gate of the second transistor receives the input signal, and a second node of the second transistor is coupled to a ground;
an inverter, for receiving the input signal and outputting an inverse signal;
a third transistor, wherein a first source/drain of the third transistor is coupled to the first voltage, a gate of the third transistor is coupled to the second source/drain of the first transistor; and
a fourth transistor, wherein a first source/drain of the fourth transistor is coupled to a gate of the first transistor and a second source/drain of the third transistor, and outputs an output signal, wherein a gate of the fourth transistor receives the inverse signal, and a second source/drain of the fourth transistor is coupled to the ground;
wherein, the first transistor and the third transistor are a first-type MOSFET, and the second transistor and the fourth transistor are a second-type MOSFET.

2. The level shifter of claim 1, wherein the inverter comprises:
a fifth transistor, wherein a first source/drain of the fifth transistor is coupled to a second voltage, and a gate of the fifth transistor receives the input signal; and
a sixth transistor, wherein a first source/drain of the sixth transistor is coupled to a second source/drain of the fifth transistor and outputs an inverse signal, a gate of the sixth transistor receives the input signal, and a second source/drain of the sixth transistor is coupled to the ground;
wherein, the fifth transistor is a third model transistor, and the sixth transistor is a fourth model transistor.

3. The level shifter of claim 2, wherein the second voltage controls the output of the first voltage.

4. The level shifter of claim 2, wherein the third model transistor is a P-type MOSFET.

5. The level shifter of claim 2, wherein the fourth model transistor is an N-type MOSFET.

6. The level shifter of claim 1, wherein the first model transistor is a P-type MOSFET.

7. The level shifter of claim 1, wherein the second model transistor is an N-type MOSFET.
